(19) United States
(12) Patent Application Publication
(10) Pub. No.: US 2023/0146861 A1
(43) Pub. Date: May 11, 2023

(54) Asynchronous Reset Physically Unclonable Function Circuit

(71) Applicant: Radiance Technologies, Inc., Huntsville, AL (US)

(72) Inventor: William Bouillon, Baton Rouge, LA (US)

(73) Assignee: Radiance Technologies, Inc., Huntsville, AL (US)

(21) Appl. No.: 17/984,141

(22) Filed: Nov. 9, 2022

Related U.S. Application Data
(60) Provisional application No. 63/277,537, filed on Nov. 9, 2021.

(51) Int. Cl. G06F 30/327

(52) U.S. Cl. CPC G06F 30/327

(57) ABSTRACT

A NCL circuit is disclosed with a combinational logic circuit between DI register banks, an input register bank having at least a first input register positioned upstream of an output register bank having at least a first output register. A completion logic circuit that sends a handshaking signal to the upstream input registers indicating that all the downstream circuits are ready for any one of two wavefronts, meaningful data wavefront and a NULL wavefront from the combination logic circuit. The NCL circuit may further have one or more observation points on outrail groups of the input registers, observing propagation of startup values to the combination logic circuit. The NCL circuit may also have one or more multiplexers allowing for selection of a primary input or the feedback signal, to control the start up values to the combinational logic circuit will powering on.

### CROSS-REFERENCE TO RELATED APPLICATIONS

This application claims benefit of U.S. provisional patent application “Asynchronous Reset Physically Unclonable Function Circuits” Ser. No. 63/277,537 filed Nov. 9, 2021. The foregoing application is hereby incorporated by reference in its entirety.

### FEDERALLY SPONSORED RESEARCH

Not applicable.

### BACKGROUND OF THE INVENTION

The technical field of the invention relates to integrated circuits, more specifically, a Physically Unclonable Function (PUF) circuit design methodology for incorporating the PUF concept into a delay-insensitive asynchronous paradigm, more specifically, NULL Convention Logic (NCL), to generate a unique signature when the circuit is powered-on.

Correct identification and authorization of digital systems becomes more relevant as society evolves into a digital world where computers are ubiquitous. CMOS digital integrated circuits (ICs) are used in many applications ranging from the Internet of Things (IoT) to military applications where sensitive data is manipulated, communicated, and stored. These ICs must be protected against exploitation, counterfeiting, and tampering from unauthorized or untrusted parties. ICs often implement cryptography as a form of protection using either software or hardware depending on application constraints. Many software cryptographic implementations are vulnerable to reverse engineering or side-channels attacks after the code is analyzed. Therefore, securing digital systems requires a paradigm shift toward security relying on the underlying hardware as opposed to reliance on software. In addition to protecting the confidentiality of sensitive data, another important aspect of secure digital design is the authentication of specific circuits. Especially in military applications and other critical systems, users should be assured the authenticity of a circuit. In other words, such

authentication should be based on what the circuit “is,” rather than the identity it claims. A popular method of circuit authentication and key generation involves the use of a Physically Unclonable Function (PUF). The first silicon-based PUF was introduced by Gas send et al. in 2002. A PUF is an unpredictable function appearing to be random and is based on physical phenomena. For example, a PUF takes advantage of process variations introduced during circuit fabrication to produce a unique, random output (a set of multi-bit binary numbers) to be used in the computation of keys for encryption or some other form of identification. The PUF circuit is dependent on randomly occurring, uncontrollable process variations, such as random threshold voltage assignment due to dopant fluctuations. PUFs are used as a challenge-response pair (CRP) in which the PUF circuit is given an input pattern (challenge) and a unique, random output (response) is generated for each circuit. The same challenge can be given to multiple, identical PUF circuits, but a unique response is generated for each. PUFs can provide authentication with simple digital circuits that consume less power and area than EEPROM/RAM methods with anti-tamper circuitry. The physical characteristic(s) which affects the PUF response is inherent from creation of the circuit and is usually introduced during the fabrication process. The response is unclonable because the process variations, which affect the PUF response, cannot be replicated and are uncontrollable. It is trivial to create a random response, but it is extremely difficult to recreate a specific PUF response.

Several other characteristics of a PUF must be taken into consideration to evaluate its effectiveness. It must be possible to easily evaluate the response of a PUF instance using a random challenge while meeting strict timing, area, power, and cost constraints required by the application. The inter-distance, the distance between two PUF responses from different PUF instances using the same challenge, should be high (ideally 50%). Reasonable changes in voltage, temperature, etc., should generate the same response for the same challenge on the same PUF circuit. The genuine manufacturer of the circuit should have no way of breaking the uniqueness property. Observing responses from the same PUF under different challenges should not lead to predictability of unobserved responses.

PUFs can be classified into two main categories: weak and strong. Weak PUFs contain a small challenge set, often only one challenge. A weak PUF, such as an SRAM PUF, typically consists of multiple instantiations of the same component to increase the range of CRPs. An advantage of weak PUFs is that statistical based model attacks are infeasible to implement due to a lack of CRP access as well as having only one CRP. However, invasive and side-channel attacks have proven successful concerning weak PUF physical access. Weak PUFs, simplistic by design, are much easier to implement than strong PUFs. Strong PUFs, such as the MUX PUF, differ from weak PUFs in that they have many possible challenges to prevent a full readout of CRPs. A design goal of strong PUFs is the resistance to statistical model attacks. This is accomplished through unpredictability and a large challenge set, but recent advances in machine learning have made statistical-based model attacks successful against many strong PUFs. A high entropy source is required to protect against this type of attack. This increases the complexity of the strong PUF, making it non-ideal to implement in many design cases. Due to the traditional weaknesses of weak and strong PUFs, a new PUF is needed to combine characteristics of both weak and strong PUFs to mitigate many known PUF attacks.

There are many PUF designs. However, no PUF uses NCL to generate a unique response. The SRAM PUF concept is relevant to this invention. The traditional SRAM cell is composed of two cross-coupled inverters and two access transistors as shown in FIG. 2. Process variations will create a slight difference in the threshold voltage of the transistors resulting in a mismatch. This mismatch will cause the cross-coupled inverters to compete and initialize to either logic ‘0’ or logic ‘1’ when powered-on. The number of bits in the responses increase linearly with the number of SRAM cells. However, like mentioned earlier, the SRAM PUF does not offer multiple CRPs and is vulnerable to invasive and side-channel attacks. The prior art NCL circuits do not maximize the opportunity to provide additional output in the response by taking the internal values at various junctions in the circuit, bypassing some gates, and rerouting the internal values to the response (i.e., circuit output). Additionally, when powering on the prior art NCL circuits, the internal feedback signal value may not be known. Thus, a need exists to determine these feedback signals prior to powering on. Also, many prior art circuits do not have a method to observe signals as the signals propagate through the prior art circuits, establishing a need for a method to observe internal signals of the circuits.

### SUMMARY OF THE INVENTION

This invention is a Physically Unclonable Function (PUF) circuit design methodology for incorporating the PUF concept into a delay-insensitive asynchronous paradigm, more specifically, NULL Convention Logic (NCL), to generate a unique signature when the circuit is powered-on, thereby providing authentication or cryptographic key generation in commercial and government applications. Leveraging the hysteresis characteristic of NCL, Asynchronous RESET (ARES) PUF circuits exhibit advantages of both weak and strong PUFs adding little to no additional overhead while mitigating many known attacks.

An objective of this invention is to use asynchronous logic to avoid the drawback of traditional synchronous systems such as clock limitations and clock tree sy s Another objective of the invention is to take advantage of the randomized SUVs of

NCL gates to produce a PUF response. A further objective of the invention is to enhance NULL convention logic circuits with the implementation of additional routing to assist generating a useful PUF response. A still further objective of the invention is to increase PUF response uniqueness by providing a NULL convention asynchronous register with a feedback input device that allows for the selection of a feedback signal from a downstream circuit element or one or more alternate input signals, hereafter referred to as “primary inputs” (e.g., primary input 1, primary input 2, primary input 3) as one of the inputs to the NULL convention asynchronous register. The feedback input device may be a switching device such as a multiplexer, also referred to as MUX in this document. The feedback input device controls the feedback signal to increase PUF response uniqueness generated by the asynchronous register. An additional objective of the invention is to reduce potential PUF response bias in NULL convention logic circuits. Another objective of the invention is to implement observation points to observe output values of circuit elements, for example outputs values of asynchronous registers.

These and other objectives are achieved by providing one or more of the following: additional routing from points in the circuit directly to the output bypassing some circuit elements; one or more asynchronous registers having additional multiplexers; observation points for monitoring output values of the asynchronous registers; and one or more multiplexers that allows for the option of selecting: a back signal from a downstream circuit that indicates either: 1) the downstream circuit is ready to receive a wavefront of meaningful data, or 2) the downstream circuit is ready to receive a NULL wavefront; or a primary input value that tells the register to either: 1) to allow a wavefront of meaningful data from its input to its output, or 2) to allow a NULL wavefront to pass from its input to its output.

When the downstream circuit indicates it is ready to receive meaningful data, the upstream asynchronous register allows meaningful data to pass from its input to its output and signals the upstream circuit through a completion gate that the input asynchronous register is ready to receive a NULL wavefront. When the downstream circuit indicates it is ready to receive NULL, the asynchronous register allows NULL to pass from its input to its output and then signals an upstream circuit via the completion gate that the input asynchronous register is ready to receive meaningful data. The preferred embodiment of the asynchronous register uses NULL convention logic threshold gates as regulators to control data and NULL wavefronts. The threshold gates receive the feedback signal ki, from the downstream circuit as an input. When the downstream circuit is ready to receive NULL, the feedback signal ki becomes ‘0’ (i.e., request for NULL). When the feedback signal ki and input signals are NULL, the threshold gates switch their outputs to NULL. When the downstream circuit is ready to receive to receive meaningful data, hereafter referred to as DATA, the feedback signal is asserted, meaning the signal has a value of ‘1’ (i.e., request for DATA). When the feedback signal is asserted and the input signal are asserted, the threshold gates assert their outputs. [0011] The asynchronous register, also called register, also uses a threshold gate to monitor the outputs of the regulating gates. This threshold gate output, completion signal ko, may be feed into a completion circuit whose output is the feedback signal ki that may be used to provide instructions to an upstream circuit. When all the outputs of the regulating gates of the asynchronous register are NULL, the completion gate, a th12b (i.e., NOR) gate, asserts the completion gate output, ko, and the completion circuit, asserts its feedback signal ki, which tells the upstream circuit to present meaningful data to the asynchronous register. Conversely, the number of regulating gates of each of the asynchronous registers needed to trigger the completion gate is the number of mutually exclusive assertion groups having inputs to the asynchronous register. When those gates assert their outputs, the completion gate output, ko, is ‘0’, which tells the upstream circuit to present a NULL wavefront to the asynchronous register. When there is more than one register, and the completion gate output, ko, for each of the registers are fed into a completion circuit. When all completion gate outputs, the ko values, are ‘0’, the completion circuit presents a feedback signal ki with a ‘0’ value to the upstream circuit (i.e., previous stage) requesting a NULL wavefront. Likewise, when all the completion gate outputs, ko signals, are asserted, the completion circuit presents a feedback signal ki with a value of ‘1’ to the upstream circuit requesting a meaningful data wavefront be presented to the asynchronous register. A mutually exclusive assertion group is a group of signal lines having a characteristic that only one line of the group may be asserted at a time.

Asynchronous registers may be placed at the input and output of a circuit or anywhere deemed appropriate in the pipeline, such as in a combinational logic circuit. The asynchronous registers at the output of the combinational logic circuit may become the input registers to another circuit or another pipeline stage. When powering on the combinational logic circuit, the value of feedback signal ki, may not be known. Thus, the input asynchronous registers may have an additional input device, such as an input multiplexer that may, prior to powering on the circuit, allow a select to be controlled to select either: the feedback signal ki from a completion circuit that is downstream; or a primary input value selected by the user.

When the primary input value is selected, after the circuit produces a response, the select can be toggled and normal NCL operations can continue. This will allow greater control to prevent a biased response. Additionally, observation points may be used to observe values of circuit elements, such as an asynchronous register output from outrail groups of the regulating gates. General Purpose Input Output (GPIO) devices may be used to observe outputs of an NCL gate. For example, the signal of an input register outrail group of a regulating gate of the input register may be observed and routed to a GPIO device, such as a GPIO pad.

The circuit, such as the combinational logic circuit, may use additional routing from internal points in the circuit directly to the output, bypassing some circuit elements and providing additional PUF responses. The combinational logic circuits may have one or more input registers and the combinational logic circuit may have “handshaking”,

“fanin”, and “fanout” signals. Additionally, completion gates output signals for each of the registers may be routed to a completion logic circuit providing a feedback signal ki to upstream registers requesting NULL or DATA wavefronts be provided (i.e., input to the upstream registers).

### BRIEF DESCRIPTION OF THE DRAWINGS

The accompanying drawings, which are incorporated in and form part of the specification, illustrate various examples of the present invention and, together with the detailed description, explain the principles of the invention.

FIG. 1 shows an NCL Gate general design.

FIG. 2 shows a SRAM cell.

FIG. 3 shows TH22 gate schematic.

FIG. 4 shows a TH22 gate potential path with inputs A=1 and B=0.

FIG. 5 shows a TH22 gate potential path with inputs A=0 and B=1.

FIG. 6 shows a full a NCL full adder example.

FIG. 7 shows an example NCL circuit with SUVs.

FIG. 8 shows an NCL XOR gate schematic.

FIG. 9 shows an NCL affine transformation structure with XOR gates.

FIG. 10 shows challenge propagation in an AES encryption core.

FIG. 11 shows a response propagation in AES encryption core.

FIG. 12 shows a response propagation re-routed to output in an AES encryption core.

FIG. 13 shows a single-bit dual-rail NCL register.

FIG. 14 shows a NCL handshaking between pipeline stages.

FIG. 15 shows an NCL handshaking with MUXes inserted.

FIG. 16 shows the single-bit dual-rail NCL register of FIG. 13 with inputs AO, A1 and Ki and with outputs Z0 and Z1.

FIG. 17 shows a transistor level diagram of a first threshold gate of FIG. 16.

FIG. 18 shows a transistor level diagram of a second threshold gate of FIG. 16.

FIG. 19 shows an illustration of an example completion gate that is a NOR gate.

FIG. 20 shows an example transistor level diagram of a MUX.

### DESCRIPTION OF THE INVENTION

Asynchronous logic circuits do not have clocks; instead, they use handshaking protocols to control the circuit behavior. Different from the bounded-delay counterpart in which gate delays are bounded and the circuit will malfunction if any gate delay exceeds the bound, quasi-delay-insensitive (QDI) style asynchronous circuits, such as NULL Convention Logic (NCL) circuits, do not assume delay bounds. Individual gate or wire delay has no impact on the correctness of the circuit output. Since signal propagation is not time dependent, NCL circuits require very little, if any, timing analysis. NCL circuits utilize multi-rail signals to achieve delay-insensitivity. The most prevalent multi-rail encoding scheme is dual-rail which contains two wires or rails, D⁰ and D¹, representing signal D. D⁰ and D¹ may represent any value from the NCL set {DATA0, DATA1, NULL} as described in the following Table 1.

TABLE 1

| | DATA0 | DATA1 | NULL | Illegal |
|---|---|---|---|---|
| D⁰ | 1 | 0 | 0 | 1 |
| D¹ | 0 | 1 | 0 | 1 |

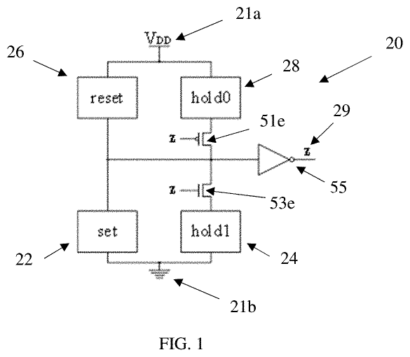

When D⁰=1, D¹=0, this corresponds to the NCL state DATA0 and Boolean logic FALSE. When D⁰=0, D¹=1, this corresponds to the NCL state DATA1 and Boolean logic TRUE. D enters a NULL state when D⁰, D¹=0 meaning the value of D is not yet available. The state D⁰=1, D¹=1 should never occur and is an illegal state because D⁰ and D¹ are mutually exclusive. Referring to FIG. 1 and Table 2 below, the NCL logic family consists of 27 threshold gates, each of which has four blocks (i.e., a set circuit 22, a hold-1 circuit 24, a reset circuit 26, and a hold-0 circuit 28) between a voltage source (i.e., VDD 21a), and a ground 21b to either change or maintain an output Z 29, as shown in the NCL gate 20 illustration of FIG. 1. There may be a Z feedback transistor, such as feedback PMOS transistor 51e between hold-0 and a driver 55 (an inverter circuit). There may be another Z feedback transistor, such as feedback NMOS transistor 53e, between the hold-1 circuit 24 and the driver 55. NCL circuits communicate using request and acknowledge signals to prevent the current DATA from overwriting the previous DATA. With the recent resurgence of asynchronous logic (e.g., IBM True North neuromorphic processor has 60-70% QDI asynchronous logic), the multi-billion-dollar semiconductor industry has been actively looking for asynchronous circuit design technologies to be adopted in commercial products. Referring again to Table 2, each NCL gate has a threshold value associated with it denoted by the naming convention. When this threshold is met, the output of the gate will be asserted.

TABLE 2

| NCL Gate | Boolean Function |
|---|---|
| TH12 | A + B |
| TH22 | AB |
| TH13 | A + B + C |
| TH23 | AB + AC + BC |
| TH33 | ABC |
| TH23w2 | A + BC |
| TH33w2 | AB + AC |
| TH14 | A + B + C + D |
| TH24 | AB + AC + AD + BC + BD + CD |
| TH34 | ABC + ABD + ACD + BCD |
| TH44 | ABCD |
| TH24w2 | A + BC + BD + CD |
| TH34w2 | AB + AC + AD + BCD |
| TH44w2 | ABC + ABD + ACD |
| TH34w3 | A + BCD |
| TH44w3 | AB + AC + AD |
| TH24w22 | A + B + CD |
| TH34w22 | AB + AC + AD + BC + BD |
| TH44w22 | AB + ACD + BCD |
| TH54w22 | ABC + ABD |
| TH34w32 | A + BC + BD |
| TH54w32 | AB + ACD |
| TH44w322 | AB + AC + AD + BC |
| TH54w322 | AB + AC + BCD |
| THxor0 | AB + CD |
| THand0 | AB + BC + AD |
| TH24comp | AC + BC + AD + BD |

Each gate is named using the format “THmn” with n inputs and a threshold of m. For example, a TH23 gate would require at least 2 of the 3 inputs to be asserted for the output to assert. An NCL gate can also have weights associated with its inputs. For example, input A in the TH34w2 gate has a weight of 2. Inputs A (weight 2) and B (weight 1) being asserted would be enough to assert the output in this gate by meeting the threshold of 3 (2+1). An important characteristic of NCL gates is their hysteresis state-holding functionality: once an output is asserted, all inputs must be de-asserted for the output to de-assert. Hysteresis is essential for maintaining delay insensitivity in NCL and is the most important characteristic of NCL relating to the ARES PUF. This property assists in generating an unpredictable start-up value (SUV) when a circuit is powered on.

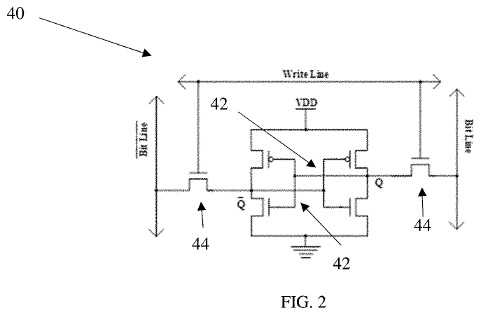

There are many existing Physically Unclonable Function (PUFs) Circuit designs. However, no PUF uses NCL to generate a unique response. Referring to FIG. 2, the SRAM PUF concept is relevant to this invention. A traditional SRAM cell, such as SRAM cell 40, may be composed of two inverters 42 that are cross coupled and two access transistors 44. Process variations will create a slight difference in the threshold voltage of the transistors resulting in a mismatch. This mismatch will cause the inverters 42 that are cross coupled to compete and initialize to either logic ‘0’ or logic ‘1’ when powered-on. The number of bits in the responses increases linearly with the number of SRAM cells 40.

However, like mentioned earlier, the SRAM PUF does not offer multiple CRPs and is vulnerable to invasive and side-channel attacks.

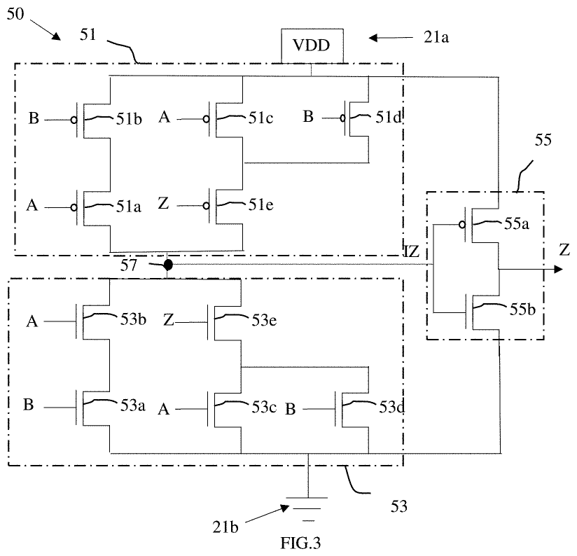

SRAM PUFs are typically classified as weak PUFs because the powering-on of an SRAM cell 40 is the only challenge to the PUF circuit. Similarly, the SUV of an NCL circuit is also unknown due to the hysteresis characteristic of NCL threshold gates. An ARES PUF circuit takes advantage of this characteristic to produce a unique response. However, the ARES PUF can have multiple challenge-response pairs, a strong PUF characteristic, because the inputs to the gates can vary. A unique response is produced depending on the input pattern as well as other process variations. Referring to FIG. 3, a TH22 gate 50 is shown. The TH22 gate includes a pull-up sub-circuit 51, a pull-down sub-circuit 53, and a driver 55. An input IZ to the driver 55 is taken from signal junction 57. The pull-up sub-circuit 51 includes a series pair of PMOS transistors, PMOS transistor 51a and PMOS transistor 51b, connecting a voltage source VDD to signal junction 57. The voltage source VDD is also connected to signal junction 57 through a parallel pair of PMOS transistors, PMOS transistor 51c and PMOS transistor 51d, which is in series with feedback PMOS transistor 51e. The pull-down sub-circuit 53 includes a series pair of NMOS transistors 53a, 53b connecting the signal junction 57 to ground. The signal junction 57 is also connected to ground through a parallel pair of NMOS transistors, NMOS transistor 53c and NMOS transistor 53d, which is in series with a feedback NMOS transistor 53e. The TH22 gate 50 has a known value when inputs A, B=0 (Z=0) and when A, B=1 (Z=1). If input A or B asserts itself from ‘0’ to ‘1’ the output will remain ‘0’ if the other input is ‘0’ as depicted in the transistor structure of FIG. 3. However, the SUV of the output, Z, is not guaranteed to be ‘0’ or ‘1’ in the cases A=1, B=0 or A=0, B=1 as denoted in Table 3.

TABLE 3

| A | B | Output | SUV |
|---|---|---|---|
| 0 | 0 | 0 | 0 |
| 0 | 1 | 0 | 0 or 1 |
| 1 | 0 | 0 | 0 or 1 |
| 1 | 1 | 1 | 1 |

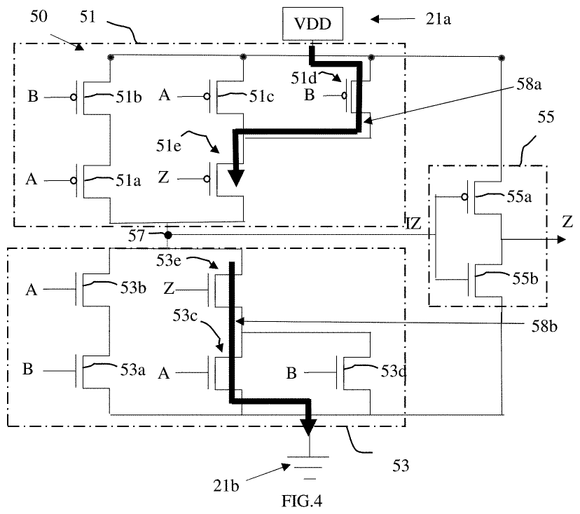

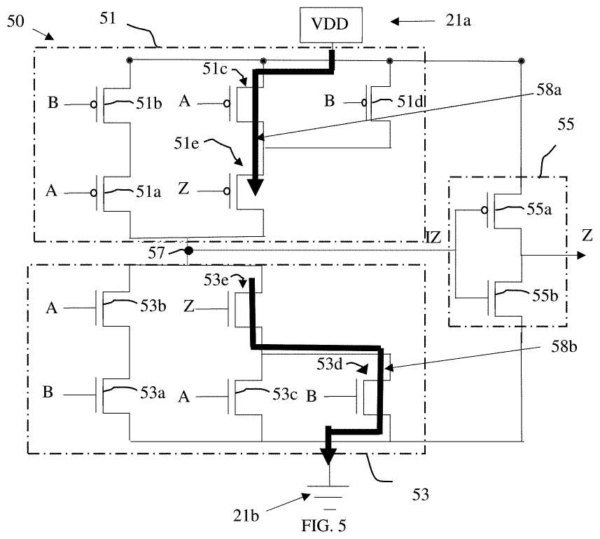

Referring to FIG. 4, when powered-on, current will flow through one of the possible highlighted (i.e., dark) paths, first path 58a or second path 58b, depending on the SUV of Z when A=1, B=0. If Z=0 then the feedback PMOS transistor 51e will conduct, resulting in IZ=1 while Z will remain a logic ‘0’. If Z=1 then the feedback NMOS transistor 53e will conduct, resulting in IZ=0 while Z will remain a logic ‘1’. A similar analysis applies when A=0, B=1 as featured in FIG. 5. The internal Z transistor has an unpredictable voltage when powered-on. This unpredictability results in a random output affected by process variations, transistor sizing, and other various characteristics.

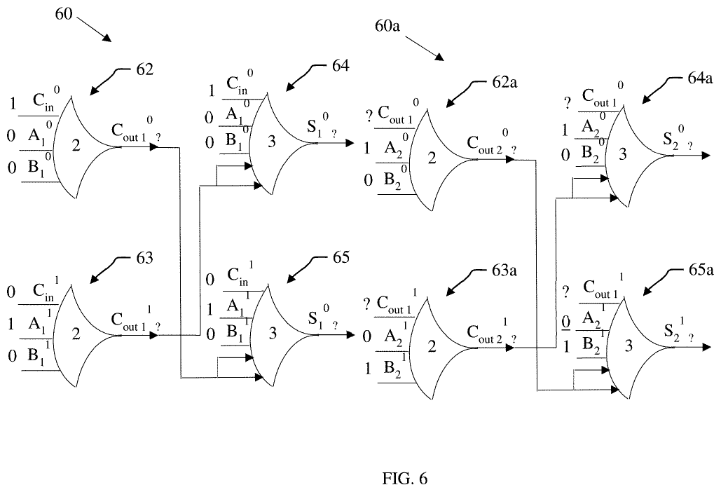

Referring to FIG. 6, potential SUVs and the resulting signal propagation respecting two NCL full adders, a first full adder 60 and a second full adder 60a, are described. Individual NCL gates will produce either a ‘0’ or ‘1’ SUV when powered-on. The SUVs in an NCL circuit will propagate throughout the circuit in an unknown manner. Referring again to FIG. 6 and Table 2, the following analysis assumes NCL gates will wait for the output of previous gates to be determined before initializing. If the challenge to the first full adder 60 and the second full adder 60a is Cᵢₙ.Rail0, A₁.Rail1, A₂.Rail0, B₂.Rail1=1 and Cᵢₙ.Rail1, A₁.Rail0, A₂.Rail1, B₂.Rail0=0, then the first two TH23 gates, 62 and 63, meet the PUF case criteria resulting in C_{out_1}.Rail0 and C_{out_1}.Rail1 initializing to either ‘0’ or ‘1’. The initialization value is unknown before powering-on the circuit. The next TH34w2 gates, 64 and 65, will either meet a PUF case and initialize to ‘0’ or ‘1’ or evaluate to ‘1’ if previous TH23 gates, 62 and 63, allow the TH34w2 threshold to be met. The final two TH23 gates, 62a and 63a, will behave similarly, depending on the value of C_{out_1}. The gates will respond to the TH22 PUF case or initialize to ‘1’ because the threshold is met. The final TH34w2 gates 64a,65a will behave like the former TH34w2 gates, 64 and 65, but the output of these gates will depend on the SUVs of Gout/and Gout 2.

A critical design decision regarding the ARES PUF is deciding which bits will constitute the PUF challenge and response. This is largely determined by the implementation of the NCL circuit: Is the PUF response used for authentication or encryption? Will the response be used internally or externally? How many viable bits are available to use? The response can be composed of circuit outputs, internally routed signals, or a combination of both. This will be determined by the PUF implementation. The challenge bits must also be selected by the designer. All inputs to the ARES PUF or a sub-section of the inputs may be chosen as the challenge. In addition, the responses do not need to be valid dual-rail numbers as they are evaluated bit-by-bit. In other words, it is perfectly fine for both rails of a dual-rail signal to be ‘1’ in a response pattern.

The ARES PUF exhibits qualities of both PUF classifications while mitigating some weaknesses associated with each type. An important benefit of the ARES PUF is the lack of additional overhead. Additional die space may not be required for PUF circuitry because the response is generated from NCL gates already present in an NCL circuit. The ARES PUF can use the GPIO devices already required by the design. Furthermore, additional circuitry required for other PUF implementations adds to overall power consumption. The ARES PUF is an intrinsic PUF, therefore no post-fabrication process is required to introduce randomness to the PUF.

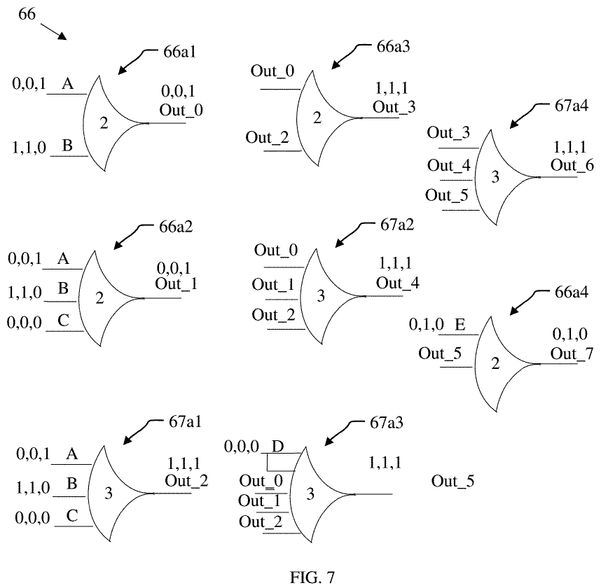

Referring to FIG. 7, shown are testing results from an example NCL Circuit 66 having four threshold 2 gates (i.e., gate one 66a1, gate two 66a2, gate three 66a3, and gate four 66a4) and four each threshold 3 gates (i.e., gate five 67a1, gate six 67a2, gate seven 67a3, and gate eight 67a4. When an NCL gate is given inputs that do not meet the threshold for assertion (e.g., A=1, B=0 or A=0, B=1 where gate one 66a1 is a TH22 gate) and then powered-on, it is not known what the initial start-up value (SUV) of this gate is. The concept can be applied to other NCL circuits. The example NCL circuit shown in FIG. 7 demonstrates this behavior. This circuit shown is fabricated in the TSMC 90 nm bulk CMOS process although other process nodes are a potential option. The purpose of this NCL circuit is to demonstrate different SUV behavior when powered-on provided different inputs. During testing, three different input patterns (i.e., first (pattern 1), second (pattern 2), and third (pattern 3)) identified by the first, second, and third values of the inputs (e.g., 0, 0, 1 of input A of gate one 66a1) were provided to the circuit with the resulting SUV also displayed. Notice that the first input pattern (A/C/D/E=0, B=1) results in Out_0=0 whereas the third input pattern (B/C/D/E=0, A=1) produces Out_0=1. It is not known beforehand what the value Out_0 will be when powered-on and is dependent on the input pattern. The second input pattern (A/C/D=0, B/E=1) results in Out_7=1 due to the threshold of the TH22 gate being met whereas other input patterns result in Out_7=0. This is not known before supplying power to the circuit though. Different input patterns (i.e., PUF challenge) can be supplied to the NCL circuit to produce a randomized value (i.e., PUF response) which can be used for authentication of a circuit identity, encryption/decryption keys, or incorporated into a watermark.

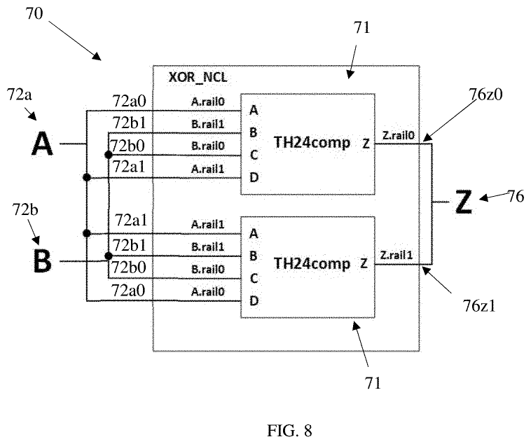

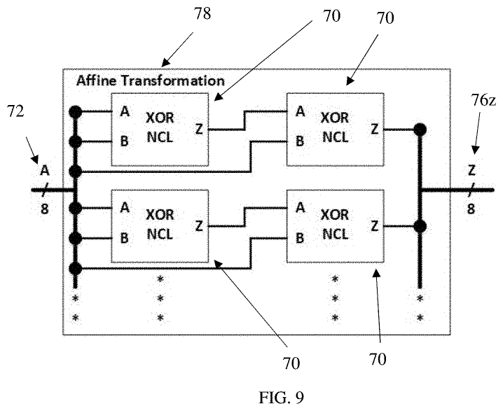

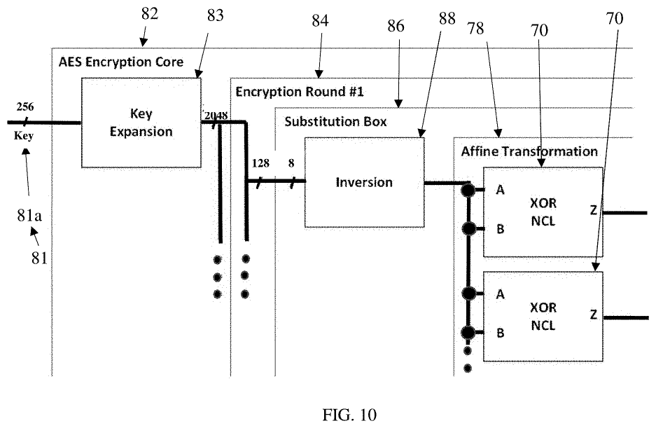

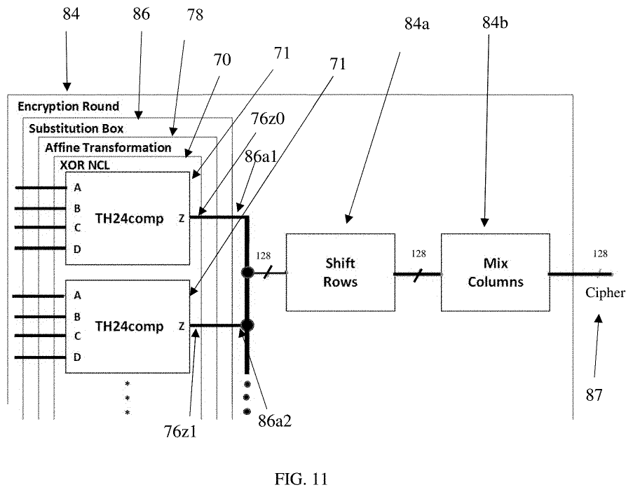

Referring to FIGS. 8-12, implementation of additional routing may assist with PUF response. An example of what this methodology looks like in a typical NCL circuit is presented in an AES encryption core 82 of FIG. 10. FIG. 8 shows the structure of an XOR gate 70 based on NCL which is comprised of two TH24comp (Z=AC+BC+AD+BD) gates 71 with XOR gate output 76. Each encryption round 84 of an AES cipher uses a substitution box 86 with 8-bits which combines the inverse function 88 with an affine transformation 78 that is invertible. FIG. 9 demonstrates the structure of an affine transformation 78 which includes several XOR gates and affine output 76z 70. A challenge to an NCL PUF involves one or more bits of an input. This example selects a Key 81 as the challenge 81a and shows the path as it propagates throughout the AES encryption core 82 in FIG. 10. The Key 81 is expanded from 256-bits to 2048-bits after Key Expansion 83 to generate another key for each encryption round 84 of the AES algorithm. Each round consists of 16 substitution boxes 86, also called S-boxes. An inversion function 88 and affine transformation 78 are also part of the path the challenge (i.e., the key 81) propagates to the XOR gates 70 (comprising TH24comp gates 71 of FIG. 8). The SUV (i.e., A.rai10 input 72a0, A.rail1 input 72a1, B.rail0 input 72b0, and B.rail1 input 72b1) of these TH24comp gates 71 can be traced to the output by the path in FIG. 11. The S-box outputs, TH24comp gates 71 first output 86a1 and TH24comp gates 71 second output 86a2, is shifted (e.g., Shift Rows 84a) and mixed (e.g., Mix Columns 84b) with the

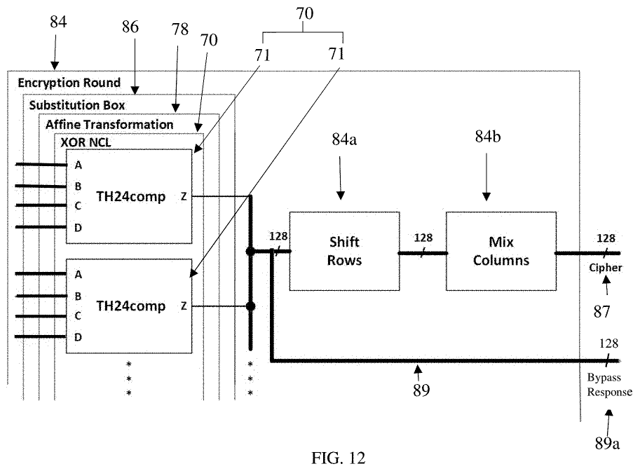

result of other S-boxes (i.e., substitution box 86) before resulting in the ciphertext, also called cipher 87. The entirety of the ciphertext, partial bits of the ciphertext, or the output of the TH24comp gates 76z0, 76z1 can be used as one response. This will depend on the designer constraints and goals. The SUVs of the TH24comp gates 71 must propagate through several other NCL gates before reaching the output of the circuit (i.e., the circuit response). If the SUVs of these other gates are heavily biased, then the response of the PUF can also be biased. For example, if an NCL gate reaches its threshold it will always initialize to a ‘1’ because that is a valid NCL input. This can cause many is to propagate throughout the PUF circuit, producing one response that is heavily biased towards ‘1’. This would result in an ineffective PUF. Referring to FIG. 12, one solution to this problem is to bypass some NCL gates between the output of a gate and the final output of the circuit. This removes the potential biasing of other NCL gates. FIG. 12 demonstrates the output of the TH24comp gates bypassing the Shift Rows 84a and Mix Columns 84b modules of the AES encryption core as shown on a bypass path 89 for a bypass response 89a. The internal gates to use for the response 89a can be carefully selected by the circuit designer to ensure that they have a 50% chance of initializing to ‘1’ or ‘0’. One output, cipher 87 in this example, obtained by routing through the Shift Rows 84a and Mix Columns 84b modules, can also be used as another response if desired. The only overhead introduced by doing this is additional routing metal and output devices/interface.

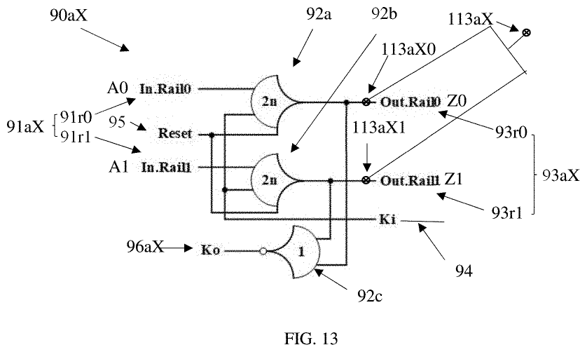

Referring to FIG. 13 and Table 1, NCL is a delay-insensitive (DI) asynchronous (i.e., clockless) paradigm, which means that NCL circuits will operate correctly regardless of when circuit inputs become available. NCL circuits are said to be correct-by-construction (i.e., no timing analysis is necessary for correct operation). NCL circuits may utilize dual-rail or quad-rail logic to achieve delay-insensitivity. When referring to element designations, an “&” is used as a placeholder for a particular register bank where “&” may be “a” for one register bank and “b” may be another register bank, and “X” is a placeholder for the register number. For example, a typical structure of a single-bit register using NCL may use a designation such as 90&X where “X” is a placeholder for the register number and the number “90&” indicates a register bank with the placeholder “&” being the letter “a” for one register bank, such as input register bank 90a at the input and “b” for another register bank, such as output register bank 90b at the output of a circuit. Referring to FIG. 13, an example single-bit register 90aX for an input register bank is shown having a first threshold gate 92a, a second threshold gate 92b, and completion gate 92c. The example single-bit register 90aX has an inrail group 91aX comprising a in.rail0 91r0 and in.rail1 91r1, and an outrail group 93aX comprising out.rail0 93r0 and out.rail1 93r1. The first threshold gate 92a has inputs A0 on in.railro 91r0 and Ki from ki-path 94, and output Z0 on out.rail0 93r0, and the second threshold gate 92b has inputs A1 on in.rail1 91r1 and Ki from ki-path 94, and output Z1 on out.rail1 93r1. The inrail group 91aX (i.e., in.rail0 91r0 and in.rail1 91r1) and the outrail group 93aX (outout.rail0 93r0 and out.rail1 93r1) together represent one state capable of assuming DATA or NULL. When both input signals A0, Ki are asserted, the output Z0 is asserted. When both input signals, A1 and Ki, are asserted, the output Z1 is asserted. After the output has been asserted, the output returns to NULL only when both inputs A0 and Ki, and inputs A1 and Ki, return to NULL. The first threshold gate 92a and the second threshold gate 92b may have a Reset, RST 95, allowing the input signals A0 and A1 to be reset to ‘0’ for 2n gates and ‘1’ for 2d gates (not shown). Operation of the circuit will assume that ‘0’ is a voltage at or near ground, and that asserted (i.e., ‘1’) is at or near the voltage source VDD. The value for the asserted voltage will be determined by the fabrication technology. The Z0 and Z1 values are also fed into the completion gate 92c having a completion signal Ko 96aX of ‘0’ when either Z0 or Z1 has a value of ‘1’. This notifies the upstream circuit that a NULL wavefront is to be sent. The completion signal Ko 96aX will have a value of ‘1’ when both Z0 and Z1 have a value of ‘0’. This notifies the upstream circuit that a meaningful data (i.e., DATA) wavefront is to be sent. There may also be sub-observation points, such as outrail0 observation point 113aX0 for the outrail0 93r0 and outrail1 observation point 113aX1 for the outrail.1 93r1, where the “X” may identify the register number and “a” indicates register bank a. The outrail0 observation point 113aX0 and the outrail1 observation point 113aX1 may be part of a register's out observation point 113aX. The sub-observation points such as outrail0 observation point 113aX0 and outrail1 observation point 113aX1 for outrail.1 93r1 can assist in determining a good challenge to use for the PUF circuit resulting in an unpredictable response.

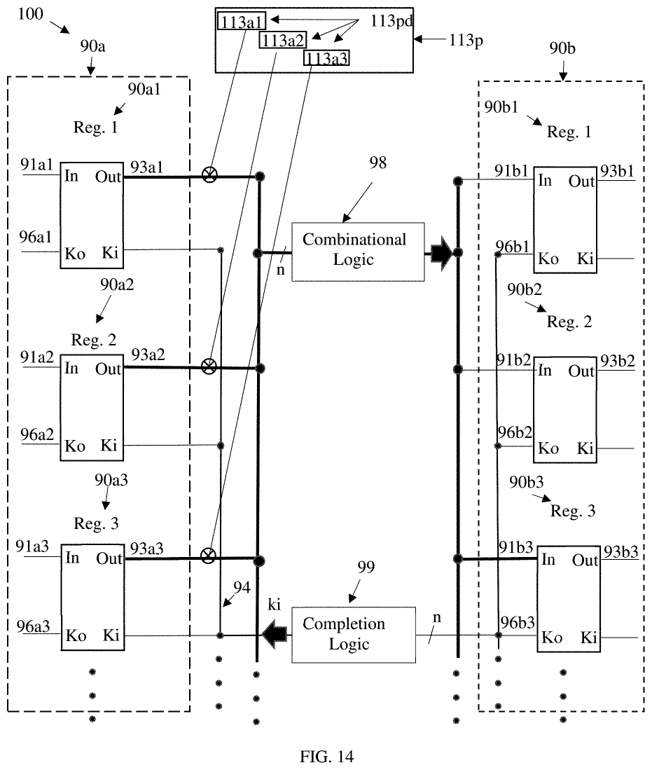

Referring to FIG. 14, the framework for NCL systems may consist of a DI combinational logic circuit 98, sandwiched between DI register banks, such as the input register bank 90a and the output register bank 90b, where the input register bank 90a has at least a first input register, input register one 90a1, and the output register bank 90b has at least a first output register, output register one 90b1, that have the same elements as example single-bit register 90aX shown in FIG. 13. A completion logic circuit, also called a completion circuit 99, will send the handshaking signal, feedback signal ki, along ki-path 94 to the upstream DI registers indicating that all the downstream circuits, such as output register one 90b1, output register two 90b2, and output register three 90b3 are either ready for a meaningful data wavefront or a NULL wavefront from the combination logic circuit 98. As shown, there are three input registers: input register one 90a1 with input register one input line 91a1 and input register one outrail group 93a1; input register two 90a2 with input register two input line 91a2

and input register two outrail group 93a2, and input register three 90a3 with input register three input line 91a3 and input register three outrail group 93a3. There are three output registers: the output register one 90b1 with output register one input line 91b1 and output register one outrail group 93b1; the output register two 90b2 with output register two input line 91b2 and output register two outrail group 93b2; and the output register three 90b3 with output register three input line 91b3 and output register three outrail group 93b3. The input register one 90a1, the input register two 90a2, and the input register three 90a3 have input register one completion signal Ko 96a1, input register two completion signal Ko 96a2, and input register three completion signal Ko 96a3, respectively. The output register one 90b1, the output register two 90b2, and the output register three 90b3 may have output register one completion signal Ko 96b1, output register two completion signal Ko 96b2, and output register three completion signal Ko 96b3, respectively. Each register may be in a register bank and may have one or more has an observation points 113&X, such as input register bank 90a as shown on FIG. 14 with input register one out observation point 113a1, a input register two out observation point 113a2, and input register three out observation point 113a3 for the input register one outrail group 93a1, input r ter two outrail group 93a2, and input register three outrail group 93a3 respectively, that ca be utilized to observe the propagation of SUVs between gates. The output of an NCL gate (e.g., output of input register one 90a1 the input register one outrail group 93a1, also the beginning of combinational logic circuit 98, or wherever deemed relevant) can be observed and routed to a GPIO device 113p that may include a GPIO pad 113pd for each signal to be probed or wire bonded. This can give a designer more post-silicon information about the PUF circuit.

Referring again to FIGS. 13 and 14, a potential source of bias in an NCL PUF circuit, such as NCL circuit 100 of FIG. 14, may originate from gates with large fanouts. An asynchronous design paradigm, NCL utilizes localized handshaking signals to coordinate DATA/NULL wavefronts between combinational blocks of logic. The handshaking signals, such as completion signal ko 96b3 for register 3 of output register bank 90b, and the feedback signal ki, alert different pipeline stages if an NCL DATA/NULL wavefront is needed. Referring to FIGS. 13-14, the handshaking signals, such as output register one completion signal ko 96b1, output register two completion signal ko 96b2, and output register three completion signal ko 96b3, are routed to a completion logic circuit, also called a completion circuit 99, where the output is the feedback signal ki routed along ki-path 94 to different registers, such as the input register one 90a1, the input register two 90a2, and the input register three 90a3 to toggle between DATA/NULL wavefronts.

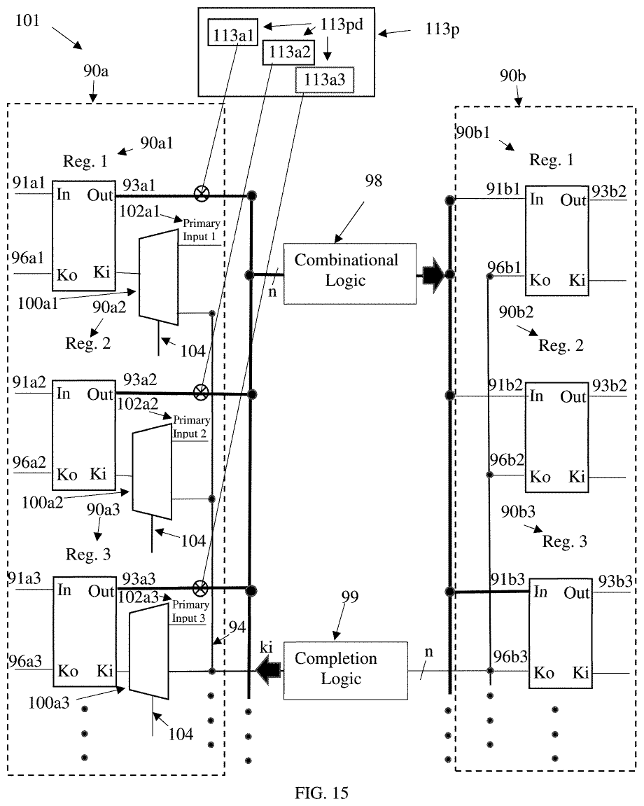

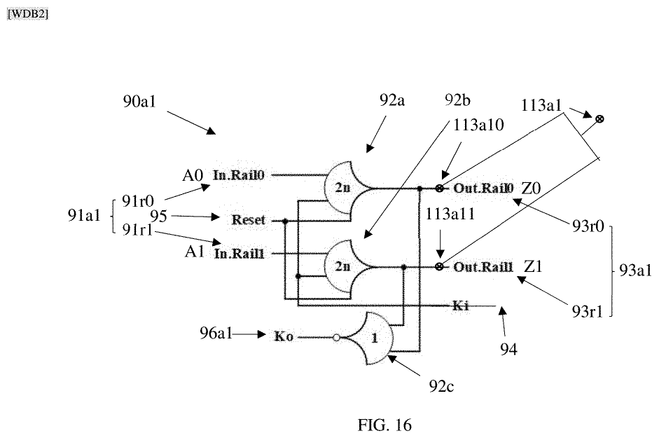

It is beneficial to have more direct access to signals with large fanouts to assist in decreasing potential bias of the PUF response. Referring to FIG. 15, one or more feedback input devices (e.g., multiplexers), such as input register one MUX 100a1, may increase PUF uniqueness. The multiplexers may be inserted to control the SUVs of a specific net if this will help generate a good PUF response. MUXes, such as an input register one MUX 100a1, an input register two MUX 100a2, and an input register three MUX 100a3 are illustrated in FIG. 15, can be added to the circuit in FIG. 14 so that the input register one 90a1, the input register two 90a2, and input register three 90a3 may receive primary input one 102a1, a primary input two 102a2, and a primary input three 102a3, respectively, prior to the NCL circuit 101 being powered on. The primary input values, such as the primary input one 102a, the primary input two 102a2, and primary input three 102a3 are selected via the input register one MUX 100a1, the input register two MUX 100a2, and input register three MUX 100a3, respectively. Before powering on the PUF circuit, such as NCL circuit 101, the PUF circuit is given primary input values such as the primary input one 102a1, primary input two 102a2, and the primary input three 102a3 which are selected via the MUXs instead of ki from the completion circuit 99. After producing a response, select 104 can be toggled and normal NCL operation can continue. This allows for greater control to prevent a biased response. [0048] FIG. 16 illustrates the two threshold gates of FIG. 13 for the input register one 90a1 having the first threshold gate 92a and the second threshold gate 92b with the reset-to-NULL NCL gate (i.e., TH22n). The first threshold gate 92a has the inputs A0 and Ki and the output Z0, and the second threshold gate 92b has the inputs A1 and Ki and the output Zl.

Each of the input rails in.rail0 91r0 and in.rail1 91r1, and the outrail group out.rail0 93r0 and out.rail1 93r1, respectively, together represent one state capable of assuming DATA or NULL. When both input signals A0, Ki are asserted, the output Z0 is asserted. When both input signals A1, Ki are asserted, the output Z1 is asserted. After the output has been asserted, the output returns to NULL only when both inputs A0 and Ki, and the inputs A1 and Ki, return to NULL. There may be an outrail0 observation point 113a10 on outrail0 93r0 and outran observation point 113a11 on out.rail1 93r1. The outrail0 observation point 113a10 and the outrail1 observation point 113a11 may be part of input register one out observation point 113a1.

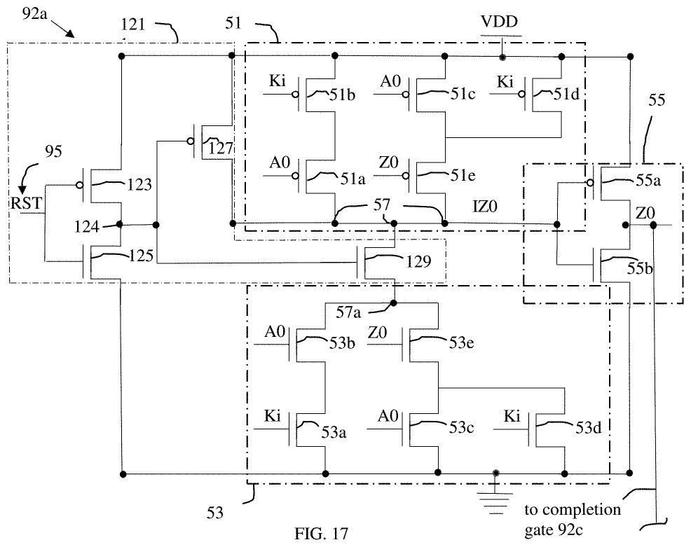

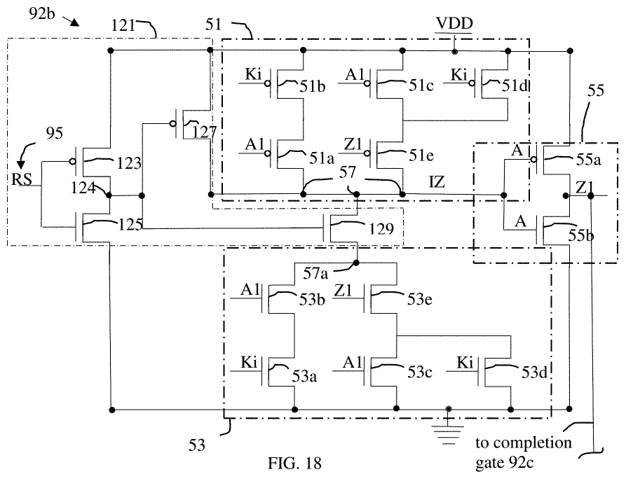

FIGS. 17-18 illustrate transistor-level circuit diagrams of a static CMOS implementation of the TH22n gate, the first threshold gate 92a and the second threshold gate 92b, of FIG. 16. Referring to FIG. 17, the implementation includes the pull-up sub-circuit 51, the pull-down sub-circuit 53, and the driver 55 of FIG. 3, plus a reset circuit 121 with the reset, RST 95. The reset, RST 95, is set equal to zero (i.e., RST 95=0) in the following gate analysis to allow for normal gate operation. The input IZ0 to the driver 55 is taken from the signal junction 57. The pull-up sub-circuit 51 includes a series pair of PMOS transistors 51a, 51b connecting a voltage source VDD to signal junction 57. The voltage source VDD is also connected to signal junction 57 through a parallel pair of PMOS transistors 51c, 51d, which is in series with feedback PMOS transistor 51e.

The pull-down sub-circuit 53 includes the series pair of NMOS transistors 53a, 53b connecting another signal junction 57a to ground. The other signal junction 57a is also connected to ground through the parallel pair of NMOS transistors 53c, 53d, which is in series with the feedback NMOS transistor 53e. The reset circuit 121 has a first reset PMOS transistor 123 connecting a reset signal junction 124 to VDD and a first reset NMOS transistor 125 connecting the reset signal junction 124 to ground. A second reset PMOS transistor 127 is in parallel to the series pair of PMOS transistors 51a and 51b connecting VDD to signal junction 57. A second reset NMOS transistor 129 connects signal junction 57 to pull down signal junction 57a. Gates of second reset PMOS transistor 127 and second reset NMOS transistor 129 are connected to reset signal junction 124. When the reset, RST 95, has a value of ‘1’ it will turn on the first reset NMOS transistor 125, thereby turning off second reset NMOS transistor 129 and turning on second reset PMOS transistor 127, pulling IZO to VDD and the driver 55 inverting IZ0 to an output value Z0 of ‘0’. When the reset, RST 95, has a value of ‘0’, the first reset PMOS transistor 123 to be turned on, thereby turning off the second reset PMOS transistor 127 and turning on the second reset NMOS transistor 129 that connects the pull-up sub-circuit 51 and pull-down sub-circuit 53.

One input signal A0 is connected to the gates of PMOS transistor 51a, PMOS transistor 51c, NMOS transistor 53b and NMOS transistor 53c. The other input signal Ki is connected to the gate of PMOS transistor 51b, PMOS transistor 51d, NMOS transistor 53a and NMOS transistor 53d. The output Z0 is connected to the gates of both feedback transistors, feedback PMOS transistor 51e and feedback NMOS transistor 53e.[0052]

When both input signals A0, Ki are ‘0’, the series pair of PMOS transistors, PMOS transistors 51a and 51b, are on, the series pair of NMOS transistors, NMOS transistors 53a and 53b are off, and the signal junction 57 is pulled to the voltage source VDD. The driver input (which is taken from the signal junction 57) is at the source voltage level, and the driver 55 switches its output Z to ‘0’. The pair of PMOS transistors, PMOS transistors 51c and 51d, are also on, as is the feedback PMOS transistor 51e. Thus, the signal junction 57 is switched to the voltage source through the pair of PMOS transistors in parallel, PMOS transistors 51c, 51d as well. All the NMOS transistors are off.

When both input signals A0, Ki are asserted, the series pair of NMOS transistors 53a and 53b are on, the series pair of PMOS transistors 51a, 51b are off, and the signal junction 57 is pulled to ground. The driver input is at the ground voltage, and the driver 55 asserts its output. The pair of NMOS transistors in parallel, NMOS transistors 53c, 53d are also on, as is the feedback NMOS transistor 53e. Thus, the signal junction 57 is switched to ground through the pair of NMOS transistors in parallel, NMOS transistors 53c, 53d as well. All the PMOS transistors are off.

When one input signal is asserted and the other is NULL, one transistor of each series pair 51a/51b, 53a/53b is on, and the other transistor is off. Thus, the series transistors do not connect the signal junction 57 either to the voltage source or to ground, and one transistor of each parallel pair 51c/51d, 53c/53d is on. The voltage of the signal junction 57 (and thus of the output Z0) is determined by the state of the feedback transistors, feedback PMOS transistor 51e and feedback NMOS transistor 53e. If the prior output Z0 was ‘0’, the feedback PMOS transistor 51e is on, the signal junction 57 is at the source voltage, and the driver output remains ‘0’. If the prior output Z0 was asserted, the feedback NMOS transistor 53e is on, the signal junction 57 is at ground, and the driver output remains asserted. Thus, the pair of PMOS transistors in series, PMOS transistors 51a, 51b and the pair of NMOS transistors in series, NMOS transistors 53a, 53b determine the output state when both inputs are NULL and when both inputs are asserted. The feedback transistors, feedback PMOS transistor 51e and feedback NMOS transistor 53e provide hysteresis when one input is asserted, and the other input is ‘0’. The pair of PMOS transistors in parallel, PMOS transistors 51c and 51d serve to hold the output ‘0’ when only one transistor is active. The pair of NMOS transistors in parallel, NMOS transistors 53c and 53d serve to hold the output ‘1’ when only one transistor is active.

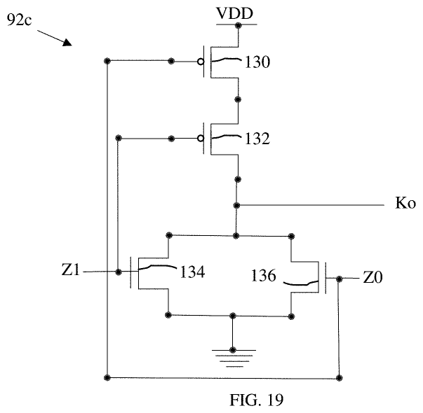

Referring to FIG. 19, an illustration of the completion gate 92c is shown. The completion gate 92c may be a NOR gate. There may be two upper PMOS transistors, a PMOS transistor 130 in series with a PMOS transistor 132, connected to two lower NMOS transistors in parallel, a NMOS transistor 134 in parallel with a NMOS transistor 136. When either ZO or Z1 is ‘1’, then the output at Ko is ‘0’, indicating a request for NULL. When ZO and Z1 are ‘0’, then output at Ko is ‘1’, indicating a request for meaningful data.

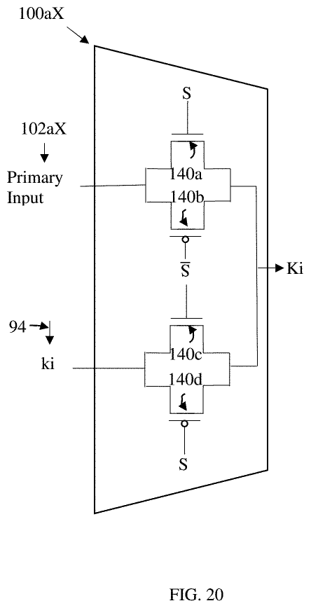

Referring to FIG. 20, an illustration of a sample input register multiplexer 100aX is shown where the “X” is a placeholder for the register number. Either the primary input 102aX or the handshaking signal, feedback signal ki along the ki-path 94 may be selected by selecting a high or low value of S to determine an input for Ki of the input register, such as the input register one 90a1 of FIG. 15. There is an upper transmission gate NMOS transistor 140a in parallel with PMOS transistor 140b. There is a lower transmission gate NMOS transistor 140c in parallel with PMOS transistor 140d. The multiplexing is essentially voltage-controlled switching. The feedback signal ki is connected to an active-low transmission gate, and the primary input 102aX signal is connected to an active-high transmission gate. When S is low, Ki equals ki; when S is high, Ki is the primary input 102aX.

Although the invention has been described with reference to one or more embodiments, this description is not meant to be construed in a limiting sense. Various modifications of the disclosed embodiments as well as alternative embodiments of the invention will become apparent to persons skilled in the art. It is therefore contemplated that the appended claims will cover any such modification or embodiments that fall within the scope of the invention.

1. A NCL circuit comprising:
a DI combinational logic circuit, between DI register banks, an input register bank and an output register bank, where the input register bank has at least a first input register and the output register bank has at least a first output register; the input register bank being up stream of the output register bank;
a completion logic circuit that sends a handshaking signal, to upstream input registers in the input register bank indicating that downstream circuits in the output register are ready for any one of two wavefronts, meaningful data wavefront and a NULL wavefront from the combination logic circuit; and
the NCL circuit comprising: one or more observation points on outrail groups of the input registers, observing propagation of startup values to the combination logic circuit

2. The NCL circuit of claim 1 further comprising one or more multiplexers, each of the multiplexer having at least a primary input and a feedback signal from the completion logic circuit, each of the multiplexers toggled to input into the input register any one of the primary input and the feedback signal.

3. A NCL circuit having a DI combinational logic circuit, between DI register banks, an input register bank and an output register bank, where the input register bank has at least a first input register and the output register bank has at least a first output register; the input register bank being up stream of the output register bank;
a completion logic circuit that sends a handshaking signal, to the upstream input registers in the input register bank indicating that the downstream circuits in the output register are ready for any one of two wavefronts, meaningful data wavefront and a NULL wavefront from the combin4.ation logic circuit; and the NCL circuit comprising: one or more observation points, on outrail groups of the input registers, observing propagation of startup values to the combination logic circuit

4. The NCL circuit of claim 3 further comprising one or more multiplexers, the multiplexers having at least a primary input and a feedback signal from the completion logic circuit, each of the multiplexers toggled to input into a completion gate of the input register any one of the primary input and the feedback signal.
